(19) United States
(12) Patent Application Publication
(10) Pub. No.: US 2024/0392104 A1
(43) Pub. Date: Nov. 28, 2024

(54) COMPOSITION, CURED FILM, DEVICE INCLUDING THE SAME, AND MANUFACTURING METHOD FOR THE CURED FILM

(71) Applicant: MERCK PATENT GMBH, DARMSTADT (DE)

(72) Inventors: AKIRA YAMASAKI, SHIZUOKA (JP); ATSUKO NOYA, SHIZUOKA (JP)

(21) Appl. No.: 18/790,880

(22) Filed: Jul. 31, 2024

Related U.S. Application Data
(63) Continuation of application No. PCT/EP2023/052145, filed on Jan. 30, 2023.

(30) Foreign Application Priority Data
Feb. 1, 2022 (JP) 2022-014207

(51) Int. Cl. C08K 3/22; C09D 5/33; C09D 7/61; C09D 133/08; H10K 59/80

(52) U.S. Cl. CPC C08K 3/22; C09D 5/004; C09D 7/61; C09D 133/08; C08K 2003/2241; H10K 59/873

(57) ABSTRACT

A composition comprising at least a polycyclic aromatic hydrocarbon-containing polymer, a scattering agent, and a thiol-containing monomer.

### CROSS REFERENCE TO RELATED APPLICATIONS

This application is a Continuation under 35 USC § 111 (a) of International Patent Application No. PCT/EP2023/052145 filed Jan. 30, 2023 which claims priority to Japanese Application No. 2022-014207 filed Feb. 1, 2022. The entire contents of these applications are incorporated herein by reference in their entirety.

### TECHNICAL FIELD

An embodiment of the present invention relates to a composition having alkali solubility. Alternatively, an embodiment of the present invention relates to a composition for the use in a cured film having a high refractive index. Alternatively, an embodiment of the present invention relates to a cured film having a high refractive index. Alternatively, an embodiment of the present invention relates to a manufacturing method of a cured film having a high refractive index. Alternatively, an embodiment of the present invention relates to a device including a cured film having a high refractive index.

### BACKGROUND

In a device using an organic material such as an organic electroluminescent device, formation of an organic film having a high refractive index is required. For example, Patent Literature 1 to 4 describe compositions including a resin having a fluorene structure and metal oxide particles to form an organic film having a high refractive index.

On the other hand, although the formation of the device using the organic material includes a step of applying and solidifying an organic material, it is necessary to prevent deterioration of the characteristics of the organic functional layer constituting the device caused by heating when the organic material is solidified.

### CITATION LIST OF PATENT LITERATURE

Japanese Laid-Open Patent Publication No. 2015-196721
Japanese Laid-Open Patent Publication No. 2018-111777
Japanese Laid-Open Patent Publication No. 2019-210310
International Patent Publication No. 2016/181422

### SUMMARY OF INVENTION

An object of an embodiment of the present invention is to provide a composition capable of forming a film at a temperature lower than that employed in the traditional art. Alternatively, an object of an embodiment is to provide a cured film having a high refractive index and formed at a temperature lower than that employed in the traditional art. Alternatively, an object of an embodiment is to provide a manufacturing method of a cured film having a high refractive index and formable at a temperature lower than that employed in the traditional art. Alternatively, an object of an embodiment is to provide a device including a cured film having a high refractive index and formed at a temperature lower than that employed in the traditional art. In addition to the above-mentioned objects, an object is to provide a composition capable of forming a cured film having excellent in HAZE, film thickness, and/or film adhesion, the cured film, and/or a device including the cured film.

According to an embodiment of the present invention, a composition includes at least:
a polycyclic aromatic hydrocarbon-containing polymer (I);
a scattering agent (II); and
a thiol-containing monomer (III).

Furthermore, according to an embodiment of the present invention, a manufacturing method of a cured film comprises:
applying the composition to a substrate to form a coating film; and heating the coating film.

Moreover, according to an embodiment of the present invention, a cured film comprises:
a polymer (A) derived from a polycyclic aromatic hydrocarbon-containing polymer and a thiol-containing monomer; and
a scattering agent.

In addition, according to an embodiment of the present invention, a display device comprising the cured film is provided.

According to an embodiment of the present invention, a composition capable of forming a film at a temperature lower than that employed in the traditional art is provided. Alternatively, according to an embodiment of the present invention, a cured film having a high refractive index and formed at a temperature lower than that employed in the traditional art is provided. Alternatively, according to an embodiment of the present invention, a manufacturing method of a cured film having a high refractive index and formable at a temperature lower than that employed in the traditional art is provided. Alternatively, according to an embodiment of the present invention, a device including a cured film having a high refractive index and formed at a temperature lower than that employed in the traditional art is provided. Preferably, in addition, a cured film excellent in HAZE, film thickness, and/or film adhesion and a device including the cured film are provided.

### DETAILED DESCRIPTION

Hereinafter, a composition, a cured film, a device including the cured film, and a manufacturing method of the cured film according to the present invention are described. Note that the composition, the cured film, the device including the cured film, and the manufacturing method of the cured film according to the present invention are not to be construed as being limited to the description contents of the embodiments and examples described below.

In this specification, symbols, units, abbreviations, and terms have the following meanings, unless otherwise limited. In this specification, unless limitedly specified, the singular forms plural forms, and “one” and “this” means “at least one”. In the present specification, unless otherwise specified, elements of a certain concept can be expressed by a plurality of species, and when the amount (for example, mass % or mol %) is described, the amount means the sum of the plurality of species. “And/or” includes all combinations of elements and also includes single use.

In the present specification, when numerical ranges are indicated using “˜” or “-”, these expressions include both endpoints, and the units are common. For example, 5 to 25 mol % means 5 mol % or more and 25 mol % or less.

In the present specification, (meth)acrylate means acrylate, methacrylate, or a mixture of acrylate and methacrylate according to the common technical knowledge.

In the present specification, a monomer means a monomer which is capable of forming a polymer (including oligomers) by reacting with other monomers.

In the present specification, the polymer may be in the form of oligomers, and a weight-average molecular weight of the polymer is not particularly limited, but is preferably 1000 to 100,000, and more preferably 2000 to 30,000. Here, the weight-average molecular weight is a styrene-estimated weight-average molecular weight measured by gel permeation chromatography.

In the present specification, an alkyl group means a group obtained by removing any one hydrogen from a linear or branched saturated hydrocarbon and includes a linear alkyl group and a branched alkyl group, and a cycloalkyl group means a group obtained by removing one hydrogen from a saturated hydrocarbon containing a cyclic structure, and optionally includes a linear or branched alkyl group as a side chain in the cyclic structure.

In the present specification, an aryl group means a group obtained by removing any one hydrogen from an aromatic hydrocarbon. An alkylene group means a group obtained by removing any two hydrogens from a linear or branched saturated hydrocarbon. An arylene group means a hydrocarbon group obtained by removing any two hydrogens from an aromatic hydrocarbon.

In the present specification, the terms “C_{x-y}”, “Cₓ˜C_{y}”, “Cₓ” and the like mean the number of carbons in a molecule or a substituent. For example, a C₁₋₆ alkyl group means an alkyl group having 1 to 6 carbons (methyl group, ethyl group, propyl group, butyl group, pentyl group, hexyl group, and the like). In addition, the term “fluoroalkyl group” used in the present specification refers to an alkyl group in which one or more hydrogens are substituted with fluorine, and the term “fluoroaryl group” refers to an aryl group in which one or more hydrogens are substituted with fluorine.

In the present specification, when a polymer has plural kinds of repeating units, these repeating units are copolymerized. The copolymerization includes any of alternating copolymerization, random copolymerization, block copolymerization, graft copolymerization, or a mixture thereof.

In the present specification, % represents mass %, and a ratio represents a mass ratio.

In the present specification, the degrees Celsius are used as the unit for temperature. For example, 20 degrees means 20 degrees Celsius.

An additive refers to a compound itself having a function of the additive (for example, in the case of a base generator, it means a compound itself that generates a base). The compound may exist in a state dissolved or dispersed in a solvent and may be added to a composition. In an embodiment of the present invention, such a solvent is preferably included in the composition according to the present invention as a solvent (VI) or as another component.

A composition according to an embodiment of the present invention includes at least:
a polycyclic aromatic hydrocarbon-containing polymer (I);
a scattering agent (II); and
a thiol-containing monomer (III).

In an embodiment, the polycyclic aromatic hydrocarbon-containing polymer included in the composition is preferably an alkali-soluble polymer. In addition, the composition can be used for producing a cured film.

In one embodiment, the composition may include a compound containing two or more (meth)acryloyloxy groups (IV).

In an embodiment, the composition may further include a solvent (V).

In one embodiment, the composition may further include a polymerization initiator (VI).

In the present specification, the “polycyclic aromatic hydrocarbon-containing polymer” means a polymer including a hydrocarbon in which an aromatic ring is condensed in a repeating unit. The polycyclic aromatic hydrocarbon-containing polymer according to the present embodiment is preferably a polymer having a fluorene structure (also referred to as a fluorene skeleton) from the viewpoint of forming a film having a high refractive index. The polycyclic aromatic hydrocarbon-containing polymer according to the present embodiment is more preferably a polymer having a cardo structure represented by the following chemical formula (1).

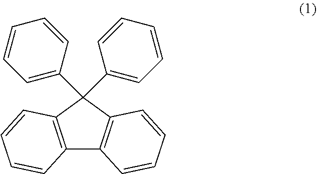 [SMILES: c1ccc(C2(c3ccccc3)c3ccccc3-c3ccccc32)cc1]

The cured film formed by this composition including the polymer having the above structure is suitable as a material for forming a film having a high refractive index. As described above, in the present specification, the term “polymer” is a concept including “oligomers”. Accordingly, the polycyclic aromatic hydrocarbon-containing polymer may be oligomers having a polycyclic aromatic hydrocarbon, and the polymer having a fluorene structure may be oligomers having a fluorene structure. Furthermore, a polymer having a cardo structure may be oligomers having a cardo structure.

In an embodiment, since a polycyclic aromatic hydrocarbon-containing polymer is an alkali-soluble polymer, it preferably has a partial structure having an acid group. The acid group is preferably an acid group having an acid dissociation constant (pKa) of 7 or less, more preferably —OH, —COOH, —SO₃H, —OSO₃H, —PO₃H₂, —CONHSO₂, and —SO₂NHSO₂—, and particularly preferably-COOH. When the alkali-soluble polymer has such an acid group, preferably a carboxy group, the solubility of the alkali-soluble polymer in a low-concentration developer can be effectively improved.

In an embodiment, the polycyclic aromatic hydrocarbon-containing polymer may include a repeating unit having two or more (meth)acryloyloxy groups. In addition, in an embodiment, the polycyclic aromatic hydrocarbon-containing polymer includes a repeating unit having one or more acid groups. Preferably, the polycyclic aromatic hydrocarbon-containing polymer includes a repeating unit having a polycyclic aromatic hydrocarbon group, two or more (meth)acryloyloxy groups, and one or more acid groups.

As the polycyclic aromatic hydrocarbon-containing polymer that may be included in the present composition, a polymer containing a cardo structure represented by the following general formula (2) described in Japanese laid-open patent publication No. 2007-223904 is represented.

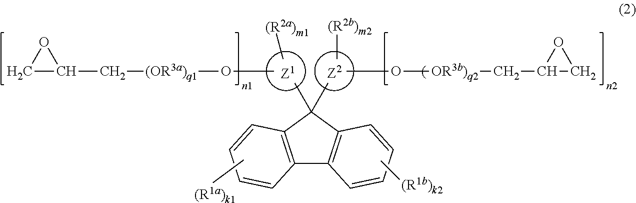

In the formula, the rings Z1 and Z2 represent the same or different aromatic hydrocarbon rings, R^{1a}, R^{1b}, R^{2a} and R^{2b} represent substituents which are the same as or at least one of which is different from the others, and R^{3a} and R^{3b} represent the same or different alkylene groups. k1 and k2 are the same or different integers of 0 to 4, m1 and m2 are each an integer of 0 or more, n1 and n2 are integers of 0 or more, and q1 and q2 are the same or different integers of 0 or more. However, n1+n2≥2.

As the polycyclic aromatic hydrocarbon-containing polymer that may be included in the present composition, a polymer containing a cardo structure represented by the following general formula (3) described in Japanese laid-open patent publication No. 2007-223904 is represented.

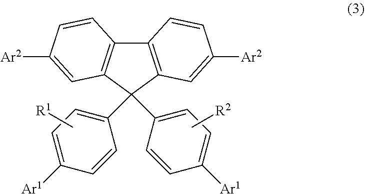

In the formula, R¹ to R² each independently represent a hydrogen atom, a linear, branched, or cyclic alkyl group or alkoxy group having 1 to 18 carbon atoms which may have a substituent, a phenyl group, a naphthyl group, or a phenoxy group which may have a substituent, or a halogen atom, and Ar¹ each independently represent a group represented by the following general formula (4) or (5). Ar² each independently represent an aryl group having 6 to 24 carbon atoms or a heteroaryl group having 3 to 24 carbon atoms which may have a substituent (excluding an amino group.

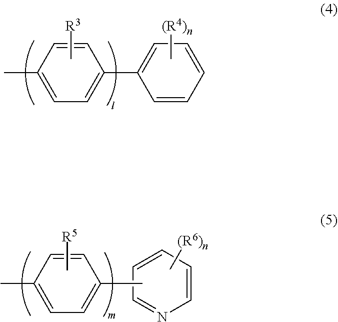

In the formula, R³ to R⁶ each independently represent a hydrogen atom, a linear, branched, or cyclic alkyl group or alkoxy group having 1 to 18 carbon atoms which may have a substituent, an aryl group or an aryloxy group having 6 to 24 carbon atoms which may have a substituent (excluding an amino group), a heteroaryl group having 3 to 24 carbon atoms, or a halogen atom. I and m represent integers of 0 to 3, and n represents an integer of 0 to 2.

As the polycyclic aromatic hydrocarbon-containing polymer that may be included in the present composition, a polymer containing a cardo structure represented by the following chemical formula (6) to (11) is represented.

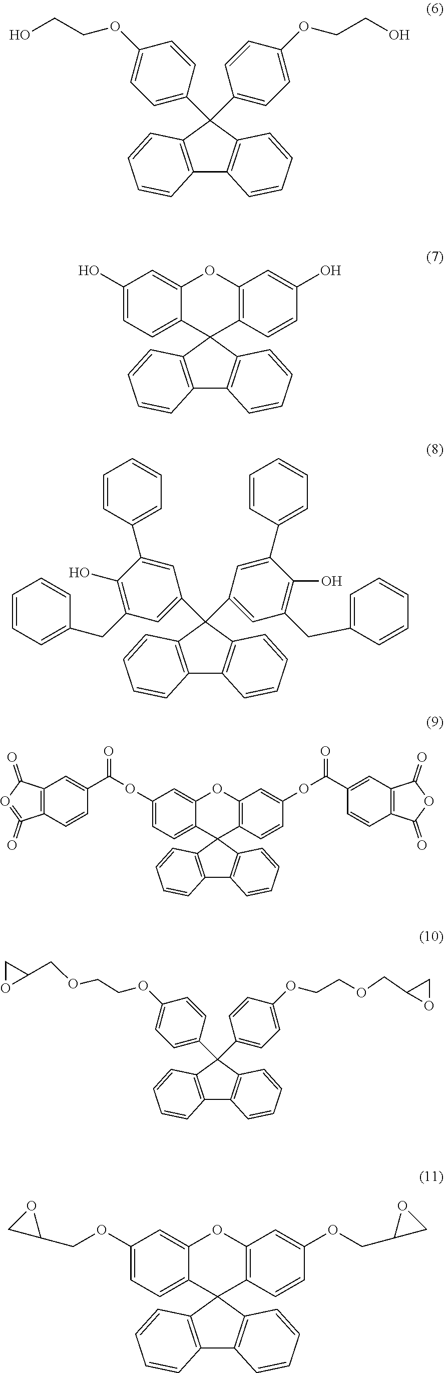

In an embodiment, the scattering agent is an organic or inorganic microparticle. Preferably, the organic microparticles are polymer microparticles, and the inorganic microparticles are metal-oxide microparticles. More preferably, the scattering agent is an inorganic microparticle. Yet more favorably, the scattering agent is an inorganic microparticle selected from a group consisting of SiO₂, SnO₂, CuO, CoO, Al₂O₃, TiO₂, Fe₂O₃, Y₂O₃, ZnO, ZnS, MgO, hollow silica particle, and a mixture including one or more of them.

In an embodiment, the scattering agent is configured to produce the Mie scattering. For example, an average particle size of the scattering agent is 350 nm to 5 μm. The scattering agent having an average particle size greater than 350 nm may lead to strong forward scattering caused by the Mie scattering. In order to form a good film, the largest average particle size of the scattering agent is preferably 5 μm or less, more preferably 500 nm to 2 μm. From the viewpoint of easiness in handling of the scattering agent and compatibility in mixing with other composition raw materials, it is preferable that the scattering agent be dispersed in an organic solvent, but it may be in the form of powder. Such a scattering agent can be suitably selected from the known materials, for example, a catalog product manufactured by Ishihara Sangyo Co., Ltd. and the like.

The content of the scattering agent in the composition according to the present embodiment is 50 to 400 mass % based on the total mass of the polycyclic aromatic hydrocarbon-containing polymer. The content of the scattering agent is preferably 100 to 300 mass %, more preferably 150 to 250 mass %, and still more preferably 200 mass %. When the scattering agent is included in these ranges, the refractive index of the cured film to be produced can be increased.

The composition according to the present embodiment includes a thiol-containing monomer, whereby the temperature at which the composition solidifies can be lowered. The thiol-containing monomer is an additive that also functions as a photopolymerization initiator. Since the thiol-containing monomer inhibits oxygen in the atmosphere, the reactivity and sensitivity of the radical polymerization reaction of the unsaturated compound by ultraviolet irradiation can be improved. As a result, when the present composition contains the thiol-containing monomer, the temperature at the time of post-baking after the ultraviolet irradiation can be lowered. In addition, the composition according to the present embodiment includes the thiol-containing monomer, whereby the crosslinking ability is improved and the adhesion to the underlayer is improved.

As the thiol-containing monomer that may be included in the composition according to the present embodiment, the following compounds (3-1) to (3-16) are represented.

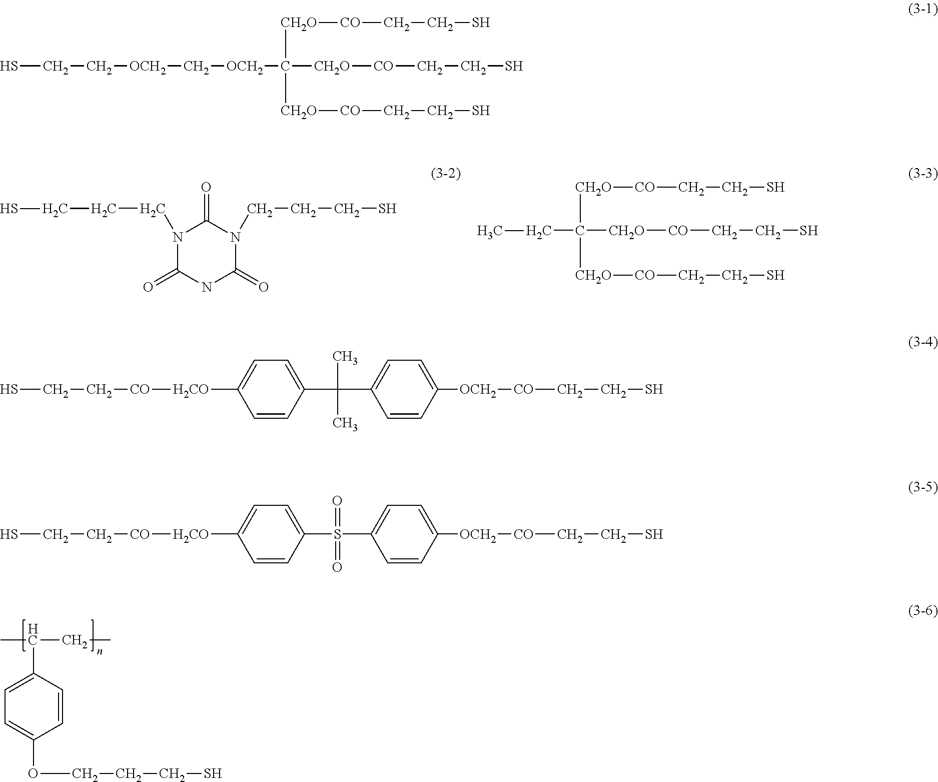

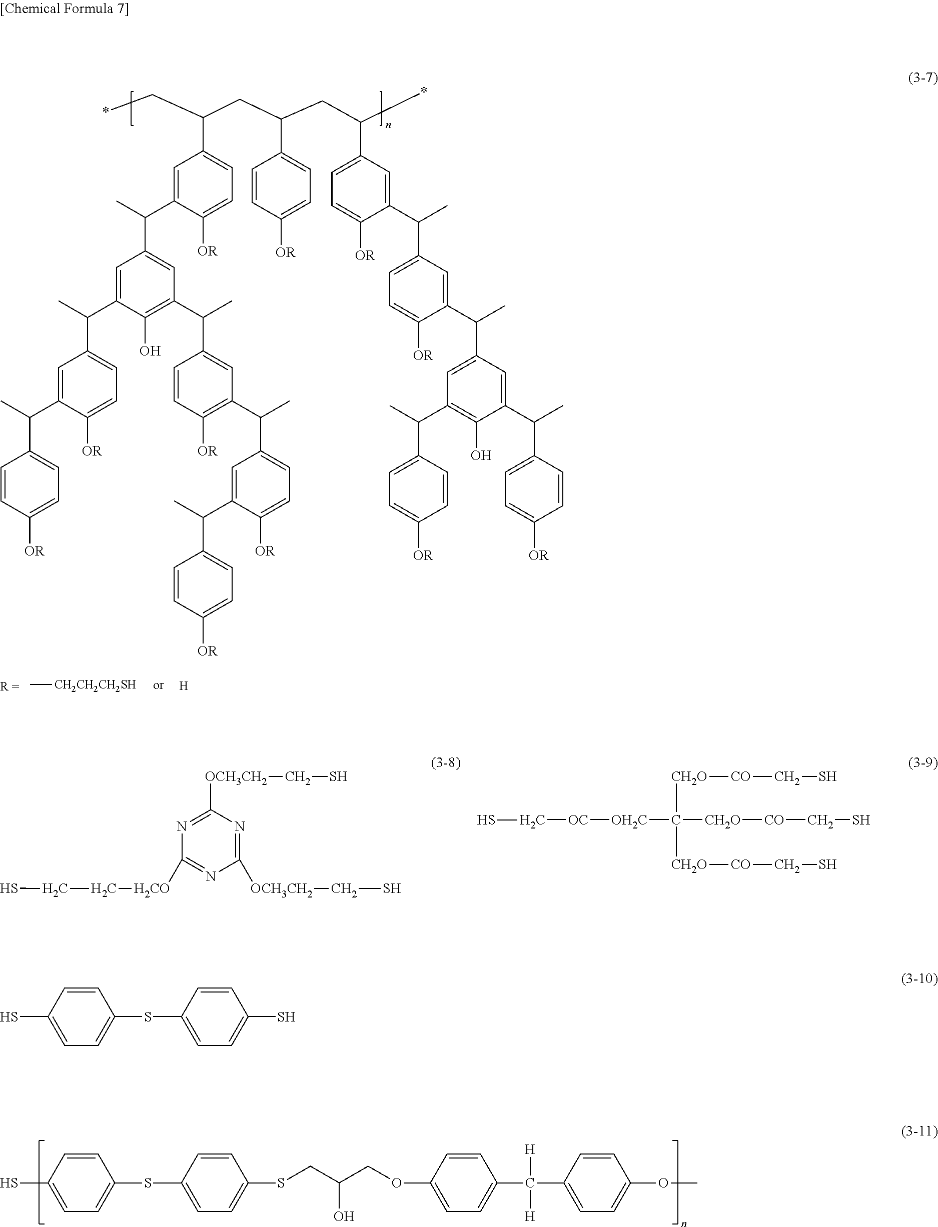

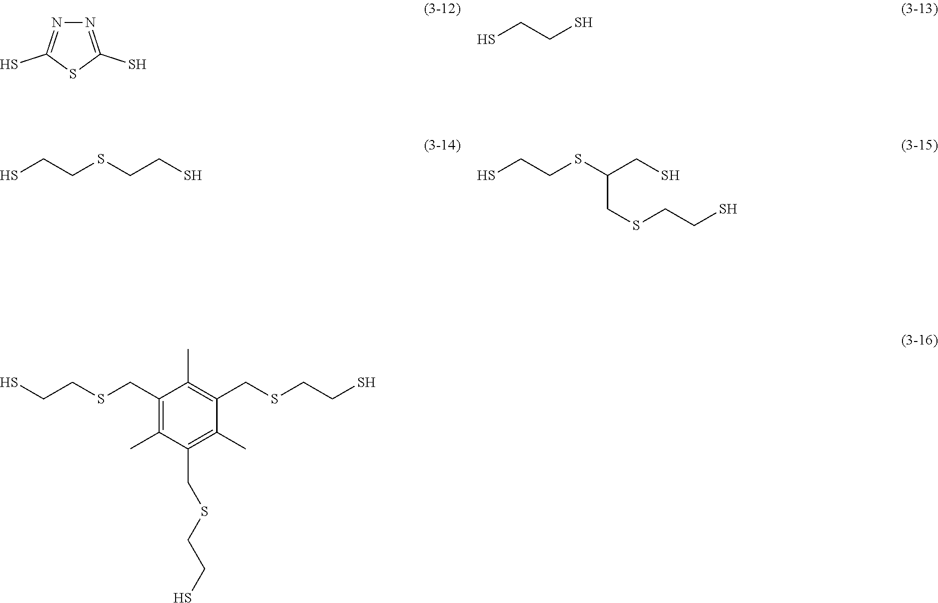

In an embodiment, the thiol-containing monomer is preferably a secondary thiol. As the secondary thiol containing monomer that may be included in the composition according to the present embodiment, the following compounds (3-17) to (3-20) are represented.

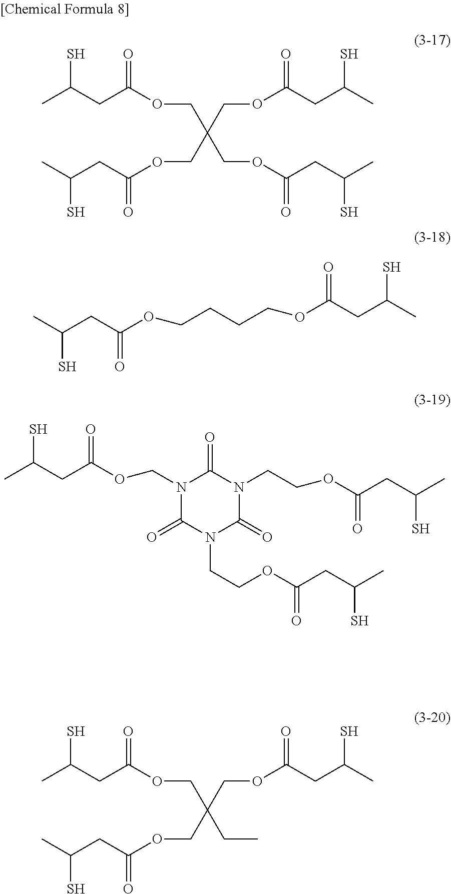

In the composition according to the present embodiment, the content of the thiol-containing monomer is 0.1 to 20 mass % based on the total mass of the polycyclic aromatic hydrocarbon-containing polymer. The content of the thiol-containing monomer is preferably 1 to 10 mass %, and more preferably 3 to 7 mass %.

Hereinafter, the compound containing two or more (meth)acryloyloxy groups may be referred to as a (meth)acryloyloxy group-containing compound for simplicity. Here, the (meth)acryloyloxy group is a generic term of an acryloyloxy group and a methacryloyloxy group. This compound is a compound capable of reacting with an acryloyl group-containing compound, an alkali-soluble polymer, or the like to form a crosslinked structure. In order to form a crosslinked structure, a compound containing two or more acryloyloxy groups or methacryloyloxy groups serving as a reactive group is required, and it is preferable to contain three or more acryloyloxy groups or methacryloyloxy groups in order to form a higher-order crosslinked structure.

As such a compound containing two or more (meth)acryloyloxy groups, an ester obtained by reacting a polyol compound having two or more hydroxyl groups (a) with two or more (meth)acrylic acids (B) is preferably used. As the polyol compound (a), a compound having a saturated or unsaturated aliphatic hydrocarbon, an aromatic hydrocarbon, a heterocyclic hydrocarbon, a primary, secondary, or tertiary amine, an ether, or the like as a basic skeleton and two or more hydroxyl groups as a substituent is represented. This polyol compound has other substituents, such as a carboxy group, a carbonyl group, an amino group, an ether bond, a thiol group, a thioether bond, or the like, as long as the effect of the present invention is not impaired.

As a preferred polyol compound, an alkyl polyol, an aryl polyol, a polyalkanolamine, cyanuric acid, dipentaerythritol, and the like are represented. Here, in the case where the polyol compound (a) has three or more hydroxyl groups, it is not necessary that all of the hydroxyl groups are reacted with meth (acrylic acid) and that they may be partially esterified. That is, the ester may have an unreacted hydroxyl group. As such an ester, tris(2-acryloxyethyl) isocyanurate, dipentaerythritol hexa(meth)acrylate, tripentaerythritol octa(meth)acrylate, pentaerythritol tetra(meth)acrylate, dipropylene glycol diacrylate, tripropylene glycol diacrylate, trimethylolpropane triacrylate, polytetramethylene glycol dimethacrylate, trimethylolpropane trimethacrylate, ditrimethylolpropane tetraacrylate, tricyclodecane dimethanol diacrylate, 1,9-nonanediol diacrylate, 1,6-hexanediol diacrylate, 1,10-decanediol diacrylate, and the like are represented. Among these esters, tris(2-acryloxyethyl) isocyanurate and dipentaerythritol hexaacrylate are preferred from the viewpoint of reactivity and the number of crosslinkable groups. In addition, two or more of these compounds may be combined to adjust the shape of the pattern to be formed. Specifically, it is preferable to combine a compound containing three (meth)acryloyloxy groups with a compound containing two (meth)acryloyloxy groups.

Such a compound is preferably a molecule which is relatively smaller than the alkali-soluble polymer from the viewpoint of reactivity. Thus, the molecular weight is preferably 2,000 or less, and preferably 1,500 or less.

The content of the (meth)acryloyloxy group-containing compound is adjusted according to the type of the polymer or the acryloyloxy group-containing compound to be used and is preferably 5 to 99.9 mass %, more preferably 30 to 70 mass % based on the total mass of the composition other than the solvent. When combined with the alkali-soluble polymer, the content is preferably 5 to 1000 mass %, more preferably 10 to 800 mass % based on the total mass of the alkali-soluble polymer from the viewpoint of compatibility with the alkali-soluble polymer. When a low-concentration developer is used, the content is preferably 30 to 800 mass %. Moreover, these (meth)acryloyloxy group-containing compounds may be used singly or in combination of two or more.

The solvent included in the composition according to the present embodiment is not particularly limited as long as it uniformly dissolves or disperses the polycyclic aromatic hydrocarbon-containing polymer, the scattering agent, the thiol-containing monomer, and a component added as necessary. Examples of the solvents that may be used in the present invention include: ethylene glycol alkyl ethers such as ethylene glycol monomethyl ether, ethylene glycol monoethyl ether, ethylene glycol monopropyl ether, and ethylene glycol monobutyl ether; diethylene glycol dialkyl ethers such as diethylene glycol dimethyl ether, diethylene glycol diethyl ether, diethylene glycol dipropyl ether, and diethylene glycol dibutyl ether; ethylene glycol alkyl ether acetates such as methylcellosolve acetate and ethylcellosolve acetate; polyethylene glycol monoalkyl ethers such as polyethylene glycol monomethyl ether and polyethylene glycol monoethyl ether; propylene glycol alkyl ether acetates such as PGMEA, propylene glycol monoethyl ether acetate, and propylene glycol monopropyl ether acetate; aromatic hydrocarbons such as benzene, toluene, and xylene; ketones such as methylethylketone, acetone, methyl amyl ketone, methyl isobutyl ketone, and cyclohexanone; alcohols such as ethanol, propanol, butanol, hexanol, cyclohexanol, ethylene glycol, and glycerin; esters such as ethyl lactate, ethyl 3-ethoxypropionate, and methyl 3-methoxypropionate; and cyclic esters such as γ-butyrolactone. Among these compounds, propylene glycol alkyl ether acetates or esters and alcohols having a linear or branched chain having 4 or 5 carbon atoms in the alkyl group are preferably used from the viewpoint of availability, easiness of handling, and solubility of an alkali-soluble material.

In the composition according to the present embodiment, the content of the solvent is preferably 1000 mass % or less based on the total mass of the polycyclic aromatic hydrocarbon-containing polymer. The content of the solvent is more preferably 10 to 1000 mass %, more preferably 300 to 900 mass %, and still more preferably 500 to 800 mass %. The viscosity of the composition can be adjusted by adjusting the content of the solvent included in the composition. In an embodiment, in order to increase the thickness of the cured film formed by the composition, it is preferable to reduce the content of the solvent included in the composition to increase the viscosity.

The polymerization initiator included in the composition according to the present embodiment is a photopolymerization initiator. The photopolymerization initiator can improve resolution by strengthening the shape of the pattern or increasing the contrast of development. The photopolymerization initiator used in the present invention is a photo-induced radical generator that emits radicals when irradiated with light (radiation). More preferably, the polymerization initiator is configured to react with the G-line (436 nm) or H-line (405 nm).

The optimal amount of the photopolymerization initiator to be added varies depending on the type and amount of the active substance generated by decomposition of the photopolymerization initiator, the required sensitivity, and dissolution contrast between the exposed portion and the unexposed portion, but is preferably 0.001 to 50 mass %, more preferably 0.01 to 30 mass % based on the total mass of the alkali-soluble polymer. From the viewpoint of preventing a situation that does not exhibit an addition effect because the dissolution contrast between the exposed portion and the unexposed portion is too low, the addition amount is preferably more than 0.001 mass %. The addition amount of the photopolymerization initiator is preferably less than 50 mass % to prevent a decrease in colorless transparency of the coating film caused by the crack formation in the coating film or conspicuous coloration resulting from the decomposition of the photopolymerization initiator, to prevent a problem in the subsequent step caused by the thermal decomposition of the photopolymerization initiator leading to deterioration of the insulating property of the cured product and gas release therefrom, and to further prevent a decrease in resistance of the coating film to the photoresist remover including monoethanolamine as the main agent.

Examples of the photopolymerization initiators include azo-based, peroxide-based, acylphosphine oxide-based, alkylphenone-based, oxime ester-based, and titanocene-based initiators. Among them, alkylphenone-based, acylphosphine oxide-based and oxime ester-based initiators are preferred, and 2,2-dimethoxy-1,2-diphenylethane-1-one, 1-hydroxy-cyclohexyl phenyl ketone, 2-hydroxy-2-methyl-1-phenylpropan-1-one, 1-[4-(2-hydroxyethoxy)phenyl]-2-hydroxy-2-methyl-1-propan-1-one, 2-hydroxy-1-{4-[4-(2-hydroxy-2-methylpropionyl)benzyl]phenyl}-2-methylpropan-1-one, 2-methyl-1-(4-methylthiophenyl)-2-morpholinopropan-1-one, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 2,4,6-trimethylbenzoyldiphenylphosphine oxide, bis(2,4,6-trimethylbenzoyl)phenylphosphine oxide, 1,2-octanedione, 1-[4-(phenylthio)-2-(O-benzoyloxime)], ethanone, 1-[9-ethyl-6-(2-methylbenzoyl)-9H-carbazol-3-yl]-1-(O-acetyloxime), and the like are represented.

The composition described above can be used to form the cured film. The cured film includes a polymer derived from the polycyclic aromatic hydrocarbon-containing polymer and the thiol-containing monomer and a scattering agent, and the polycyclic aromatic hydrocarbon-containing polymer and the thiol-containing monomer are polymerized by a polymerization reaction. When the composition contains the aforementioned compound containing two or more (meth)acryloyloxy groups, the aromatic hydrocarbon-containing polymer, the thiol-containing monomer, and the compound containing two or more (meth)acryloyloxy groups are polymerized to form the cured film.

The cured film has an average film thickness of 1 to 20 μm. Preferably, the average film thickness of the cured film is 1.5 to 15 μm, more preferably 2 to 10 μm. As described above, the cured film having a large film thickness can be obtained by adjusting the viscosity of the composition according to the present embodiment.

The cured film has a refractive index of 1.6 or more at a wavelength of 550 nm. The refractive index of the cured film is preferably 1.6 to 2.3. The refractive index of the cured film is more preferably 1.7 to 2.2, and still more preferably 1.8 to 2.1. The cured film having such a high refractive index is suitable as a film disposed on a light extraction side of an organic electroluminescent element.

The transmittance of the cured film at a wavelength of 550 nm is 60% or more. The transmittance of the cured film is preferably from 60% to 99%, more preferably from 70% to 98%, more preferably from 80% to 95%, and still more preferably from 85% to 95%. The cured film having such a high transmittance is suitable as a film disposed on a light extraction side of an organic electroluminescent element.

A manufacturing method of the cured film includes a step of applying the composition to a substrate to form the coating film, and a step of heating the coating film. Preferably, the manufacturing method of the cured film further includes a step of exposing the coating film and a step of developing the coating film. More preferably, the manufacturing method of the cured film includes a step of applying the composition according to the present embodiment to the substrate to form the coating film, a step of exposing the coating film, a step of developing the coating film, and a step of heating the coating film in this order, and further preferably includes a pre-baking step after the coating step and before the exposure step. The method for forming the cured film of the present invention will be described below in the order of steps.

### (1) Coating Process

First, the composition according to the present embodiment is applied to a substrate. The formation of the coating film of the composition according to the present embodiment can be performed by any method conventionally known as a coating method of a photosensitive composition. Specifically, any method can be arbitrarily selected from dip coating, roll coating, bar coating, brush coating, spray coating, doctor coating, flow coating, spin coating, slit coating, and the like.

In addition, as a base material on which the composition is applied, an appropriate base material such as a silicon substrate, a glass substrate, and a resin film can be used. Various types of semiconductor elements and the like may be formed on these substrates as necessary. When the base material is a film, gravure application is also available. If desired, a drying step may be separately performed after the coating. If necessary, the coating process may be repeated once, twice, or more to obtain a desired thickness of the formed coating film.

### (2) Pre-Baking Process

After the coating film is formed by applying the composition, it is preferred to pre-bake (pre-heating process) the coating film in order to dry the coating film and reduce the residual amount of the solvent in the coating film. The pre-baking step can generally be carried out at a temperature from 40 to 150° C., preferably from 50 to 100° C., for 10 to 300 seconds, preferably for 30 to 120 seconds in the case of a hot plate or for 1 to 30 minutes in the case of a clean oven.

### (3) Exposure Process

After the coating film is formed, the surface of the coating film is irradiated with light, if desired. As a light source used for the light irradiation, any light source conventionally used in the patterning method can be used. As such a light source, lamps such as high-pressure mercury lamps, low-pressure mercury lamps, metal halides, and xenon, laser diodes, a LED, and the like are represented. Ultraviolet rays such as g-rays, h-rays, and i-rays are usually used as the irradiation light. It is common to use 360 to 430 nm lights (high-pressure mercury lamps) for the several μm to several tens of μm patterning except for ultrafine processing of a semiconductor. The energy of the irradiation light is generally 5 to 2000 nJ/cm², preferably 10 to 1000 mJ/cm², depending on the light source or the thickness of the coating film. The irradiation light energy is preferably higher than 10 mJ/cm² from the viewpoint of obtaining sufficient resolution and is preferably 2000 mJ/cm² or less from the viewpoint of preventing exposure and halation.

A common photomask can be used to apply the light in a pattern shape. Such photomasks can be arbitrarily selected from those known in the art. The environment at the time of irradiation is not particularly limited but may generally be an ambient atmosphere (the atmosphere) or a nitrogen atmosphere. When the film is formed on the entire surface of the substrate, the entire surface of the substrate may be irradiated with light. In the present invention, a pattern film also includes a case where the film is formed on the entire surface of the substrate.

### (4) Post-Exposure Heating Process

After exposure, post-exposure heating (Post Exposure Baking) can be performed, if necessary, in order to accelerate the interpolymer reaction in the film by the reaction initiator generated at the exposure site. Unlike the heating step (6) described below, this heating treatment is performed not to completely cure the coating film but is performed so that only a desired pattern remains on the substrate after development and other portions can be removed by development. Therefore, it is not essential in the present invention.

When the post-exposure heating is performed, a hot plate, an oven, a furnace, or the like can be used. The heating temperature should not be excessively high since it is not preferable that the acid in the exposed region generated by the light irradiation diffuses to the unexposed region. From this viewpoint, the range of the heating temperature after exposure is preferably from 40° C. to 150° C., and more preferably from 60° C. to 120° C. Stepwise heating can also be applied as needed to control the curing rate of the composition. The atmosphere at the time of heating is not particularly limited and may be selected from an inert gas such as nitrogen, a vacuum, a reduced pressure, an oxygen gas, and the like for the purpose of controlling the curing rate of the composition. Further, the heating time is preferably equal to or more than a certain time in order to maintain a higher uniformity of the temperature history in the wafer surface and is preferably not excessively long in order to suppress diffusion of the generated acid. From this viewpoint, the heating time is preferably from 20 seconds to 500 seconds, and more preferably from 40 seconds to 300 seconds.

### (5) Development Process

After the exposure, the post-exposure heating is performed as necessary, and then the coating film is subjected to the development treatment. As a developer used in development, any developer conventionally used for development of a photosensitive composition can be used. As preferred developers, alkaline developers which are aqueous solutions of alkaline compounds such as tetraalkylammonium hydroxide, choline, alkali metal hydroxides, alkali metal metasilicates (hydrates), alkali metal phosphates (hydrates), a sodium carbonate aqueous solution, ammonia, alkylamines, alkanolamines, and heterocyclic amines are represented, and particularly preferred alkaline developers are an aqueous tetramethylammonium hydroxide solution, an aqueous potassium hydroxide solution, an aqueous sodium hydroxide solution, and an aqueous sodium carbonate solution. The alkali developer may further contain a water-soluble organic solvent such as methanol or ethanol, or a surfactant, if necessary. In the present invention, development can be performed using a developer having a lower concentration than a 2.38 mass % TMAH developer which is usually used as a developer. As such developers, a 0.05 to 1.5 mas % aqueous solution of TMAH, a 0.1 to 2.5 mass % aqueous sodium of sodium carbonate, and a 0.01 to 1.5 mass % aqueous solution of potassium hydroxide are represented. The development time is usually 10 to 300 seconds, preferably 30 to 180 seconds.

The developing method can also be arbitrarily selected from conventionally known methods. Specifically, the methods such as dipping in a developer, paddles, showers, slits, cap coating, and spraying are represented. By this development, it is possible to obtain a pattern. It is preferable to perform water washing after the development is performed.

### (6) Heating Process

The coating film is cured by heating. The heating apparatus used in the heating step may be the same as that used for the post-exposure heating. The heating temperature in the heating step is 70 to 120° C. because the composition according to the present embodiment contains the thiol-containing monomer. More preferably, the coating film is heated and cured at 75 to 100° C., and more preferably, the coating film is heated and cured at 80 to 90° C. On the other hand, in order to accelerate the curing reaction and obtain a sufficiently cured film, the curing temperature is preferably 70° C. or higher, and more preferably 80° C. or higher. The heating time is not particularly limited and is generally 10 minutes to 24 hours, preferably 20 minutes to 3 hours. Note that the heating time is a time after the temperature of the patterned film reaches a desired heating temperature. Usually, it takes several minutes to several hours for the patterned film to reach the desired temperature from the temperature before heating.

### [Display Device]

The cured film according to the present embodiment can be used as a film disposed in a display device. Since the cured film has a high refractive index, it can be suitably applied to a display device using an organic electroluminescent element such as an organic electroluminescent display. In particular, the cured film according to the present embodiment can be suitably used for the layer disposed between the light-emitting layer and the surface of the display device.

Preferred embodiments are listed below.

Embodiment 1-A Composition Including at Least:
a polycyclic aromatic hydrocarbon-containing polymer (I);
a scattering agent (II); and
a thiol-containing monomer (III).

Preferably, the polycyclic aromatic hydrocarbon-containing polymer is an alkali-soluble polymer. Further, preferably, the composition of the present embodiment is a composition for producing a cured film.

### Embodiment 2

The composition described in the embodiment 1, wherein the polycyclic aromatic hydrocarbon-containing polymer (I) includes a fluorene structure. Preferably, it includes a cardo structure.

### Embodiment 3

The composition described in the embodiment 1 or 2, wherein the scattering agent (II) is an organic or inorganic microparticle, preferably the organic microparticle is a polymer microparticle while the inorganic particulate is a metal oxide microparticle, more favorably the scattering agent is an inorganic microparticle, and still preferably the scattering agent is an inorganic microparticle selected from SiO₂, SnO₂, CuO, CoO, Al₂O₃, TiO₂, Fe₂O₃, Y₂O₃, ZnO, ZnS, MgO, hollow silica particles, and a group consisting of a mixture of one or more thereof. In addition, preferably, the scattering agent is configured to cause the Mie scattering.

### Embodiment 4

The composition described in any one of the embodiments 1 to 3, wherein the content of the scattering agent (II) is 50 mass % or more and 400 mass % or less based on the total mass of the polycyclic aromatic hydrocarbon-containing polymer (I). It is preferably 100 to 300 mass %, more preferably 150 to 250 mass %, and more preferably 200 mass %.

### Embodiment 5

The composition described in any one of the embodiments 1 to 4, wherein the content of the thiol-containing monomer (III) is from 0.1 to 20 mass % based on the total weight of the polycyclic aromatic hydrocarbon-containing polymer (I). It is preferably 1 to 10 mass %, more preferably 3 to 7 mass %. Preferably, the thiol-containing monomer is a secondary thiol.

### Embodiment 6

The composition described in any one of the embodiments 1 to 5, wherein the polycyclic aromatic hydrocarbon-containing polymer (I) includes a repeating unit having two or more (meth)acryloyloxy groups. Preferably the polycyclic aromatic hydrocarbon-containing polymer (I) includes a repeating unit having one or more acid groups.

Moreover, preferably, the polycyclic aromatic hydrocarbon-containing polymer includes a polycyclic aromatic hydrocarbon group, two or more (meth)acryloyloxy groups, and a repeating unit having one or more acid groups.

### Embodiment 7

The composition described in one of the embodiments 1 to 6, wherein the composition (IV) further includes a compound including two or more (meth)acryloyloxy groups. Preferably, the compound containing two or more (meth)acryloyloxy groups is a monomer.

### Embodiment 8

The composition described in any one of the embodiments 1 to 7, wherein the composition further includes a solvent (V). The content of the solvent is preferably equal to or less than 1000 mass % based on the total weight of the polycyclic aromatic hydrocarbon-containing polymer (I). It is more preferably 10 to 1000 mass %, more preferably 300 to 900 mass %, and still more preferably 500 to 800 mass %.

### Embodiment 9

The composition described in any one of the embodiments 1 to 8, wherein the composition (VI) further contains a polymerization initiator. Preferably, the polymerization initiator is a photopolymerization initiator. More preferably, the polymerization initiator is configured to react with the G-line (436 nm) and the H-line (405 nm).

### Embodiment 10

A manufacturing method of a cured film including:
applying the composition described in any one of the embodiments 1 to 9 to a substrate to form a coating film; and
heating the coating film.

Preferably, the step of heating the coating film performs heating and curing at 70 to 120° C. More preferably, the heating and curing are performed at 75 to 100° C., and more preferably, the heating and curing are performed at 80 to 90° C.

### Embodiment 11

A cured film manufactured or capable of being manufactured by the method of the embodiment 10.

### Embodiment 12

A cured film including:
polymer (A) derived from a polycyclic aromatic hydrocarbon-containing polymer and a thiol-containing monomer; and
a scattering agent.

### Embodiment 13

The cured film described in the embodiment 11 or the embodiment 12, where an average film thickness is 1 to 20 μm. The average film thickness is preferably 1.5 to 15 μm and more preferably 2 to 10 μm.

### Embodiment 14

The cured film described in any one of the embodiments 11 to 13, wherein a refractive index at a wavelength of 550 nm is 1.6 or more. The refractive index at the wavelength of 550 nm is preferably from 1.6 to 2.3. The refractive index at the wavelength of 550 nm is more preferably 1.7 to 2.2 and is still more preferably 1.8 to 2.1.

### Embodiment 15

The cured film described in any one of the embodiments 11 to 14, wherein a transmittance at a wavelength of 550 nm is 60% or more. The transmittance at the wavelength of 550 nm is preferably 60 to 99%, more preferably 70 to 98%, more preferably 80 to 95%, and still more preferably 85 to 95%.

### Embodiment 16

A display device including the cured film described in any one of the embodiments 12 to 15. Preferably, the cured film is disposed between a surface of the display device and a light-emitting layer.

### EXAMPLES

Hereinafter, the present invention is described in detail with reference to Examples. However, the present invention should not be construed as being limited to the description of the Examples shown below.

### Example 1

A solution having a solid content ratio of 35 mass % was prepared by adding a 100 mass % of acrylic oligomers (GA-5060P, Osaka Gas Chemical Co., Ltd.) having a fluorene structure as a polycyclic aromatic hydrocarbon-containing polymer A, a 200 mass % of titania dispersion A as a scattering agent, 3 mass % of pentaerythritol tetrakis(3-mercaptobutyrate) (Karenz MT PE-1, Showa Denko Co., Ltd.) as a thiol-containing monomer, 20 mass % of caprolactone-modified tris-(2-acryloxyethyl) isocyanurate (A-9300-1CL, Shin Nakamura Chemical Industry Co., Ltd.) as a compound containing 2 or more (meth)acryloyloxy groups, a 3 mass % of oxime-type elastomer (Adeka Articles NCI-831E, ADEKA Co., Ltd.) as a photopolymerization initiator, and propylene glycol monomethyl ether acetate (Showa Denko Co., Ltd.) as a solvent, thereby obtaining a composition of Example 1.

### Example 2

A solution having a solid content ratio of 40 mass % was prepared by changing the scattering agent A to a titania dispersion B (Ishihara Sangyo Co., Ltd.) as a scattering agent B and adding each material to propylene glycol monomethyl ether acetate at the ratio shown in Table 1, thereby obtaining the composition of Example 2.

### Example 3

A solution having a solid content ratio of 35 mass % was prepared by adding 100 mass % of acrylic oligomers having a fluorene structure (Ogsol CR-1030, Osaka Gas Chemical Co., Ltd.) as a polycyclic aromatic hydrocarbon-containing polymer A, a 200 mass % of titania dispersion A as a scattering agent A, a 3 mass % of pentaerythritol tetrakis(3-mercaptobutyrate) (Karenz MT PE-1, Showa Denko Co., Ltd.) as a thiol-containing monomer, a 20 mass % of caprolactone-modified tris-(2-acryloxyethyl) isocyanurate (A-9300-1CL, Shin-Nakamura Chemical Co., Ltd.) as a compound containing two or more (meth)acryloyloxy groups, a 3 mass % of oxime-type elastomer (ADEKA, Adeka's Articles NCI-831E, Inc.) as a photopolymerization initiator, and propylene glycol monomethyl ether acetate (Showa Denko Co., Ltd.) as a solvent, thereby obtaining a composition of Example 3.

### Example 4

A solution having a solid content ratio of 40 mass % was prepared by changing the scattering agent A to a titania dispersion B (Ishihara Sangyo Co., Ltd.) as a scattering agent B and adding each material to propylene glycol monomethyl ether acetate at the ratio shown in Table 1, thereby obtaining the composition of Example 4.

### Example 5

Instead of Example 1, a solution having a solid content ratio of 40 mass % was prepared by adding each material to propylene glycol monomethyl ether acetate at the ratio shown in Table 1, thereby obtaining the composition of Example 5. Titania powder (Ishihara Sangyo Co., Ltd.) was used.

### Comparative Example 1

A solution having a solid content ratio of 25 mass % was prepared by changing the polycyclic aromatic hydrocarbon-containing polymer A to a 100 mass % of acrylic monomer having a fluorene structure (Ogsol GA-5060P, Osaka Gas Chemical Co., Ltd.) as the polycyclic aromatic hydrocarbon-containing polymer B and adding each material to propylene glycol monomethyl ether acetate at the ratios listed in Table 1 without adding any scattering agent, thereby obtaining a composition of Comparative Example 1.

### Comparative Example 2

A solution having a solid content ratio of 25 mass % was prepared by adding each material to propylene glycol monomethyl ether acetate at the ratios shown in Table 1 without adding the polycyclic aromatic hydrocarbon-containing polymer, thereby obtaining a composition of Comparative Example 2.

TABLE 1

| | | | | | | | Comparative | |
|---|---|---|---|---|---|---|---|---|
| | | Examples | | | | | examples | |
| | | 1 | 2 | 3 | 4 | 5 | 1 | 2 |
| Fluorene-based | CR-1030 | — | — | 100 | 100 | 100 | — | — |
| acrylate polymer | | | | | | | | |
| Fluorene-based | GA-5060P | 100 | 100 | — | — | — | 100 | — |
| acrylate monomer | | | | | | | | |
| Monomer | A-9300-1CL | 20 | 10 | 20 | 10 | 10 | — | 100 |
| Photoinitiator | NCI-831E | 3 | 3 | 3 | 3 | 3 | 3 | 3 |
| Pigment | Titania dispersion A | 200 | — | 200 | — | — | — | 100 |
| | Titania dispersion B | — | 200 | — | 200 | — | — | — |
| | Titania powder | — | — | — | — | 200 | — | 0 |
| Thiol-containing | Karenz MT PE-1 | 3 | 3 | 3 | 3 | 3 | 3 | 3 |
| monomer | | | | | | | | |
| Solvent as a | PGMEA | — | — | — | — | — | — | — |
| residue | | | | | | | | |
| Properties | Refractive index at | 1.7 | 1.8 | 1.81 | 2.06 | 3.28 | 1.67 | 1.63 |
| | 550 nm | | | | | | | |
| | Transmittance (%) | 90 | 87 | 90 | 87 | 80 | 90 | 87 |
| | at 550 nm | | | | | | | |
| | HAZE | 1 | 2 | 1 | 1.8 | 5 | 0.05 | 4 |
| | Film thickness | A | A | A | A | A | B | C |
| | Adhesion | A | A | A | A | A | A | B |

### Preparation of Cured Film

The compositions of Examples 1 to 5 and Comparative Examples 1 to 2 were applied on an alkali-free glass substrate with a spin-coater (MS-A100, MIKASA), pre-baked on a hot plate (HHP-411V, AS ONE) at 100° C. for 90 seconds, after the application, and adjusted to have an average film thickness of 2 μm. An i-ray exposure machine (PLA-501, Canon) was used for exposure at 1000 mJ/cm². The exposed substrate was placed in an oven (DP-200, Yamato) at 100° C. and heated for 60 minutes to accelerate curing of the polymer.

### Refractive Index Measurement

For the cured films of Examples 1 to 5 and Comparative Examples 1 to 2, the refractive indexes at a wavelength of 550 nm were measured. The refractive index was measured using an ellipsometer (M-2000, manufactured by J.A. Woollam Japan Co., Ltd.). Measurement results are shown in Table 1.

### Measurement of Transmittance

For the cured films of Examples 1 to 5 and Comparative Examples 1 to 2, transmittances at a wavelength of 550 nm were measured. For measuring the transmittance, an ultraviolet-visible spectrophotometer (UV-2600, manufactured by Shimadzu Corporation) was used. Measurement results are shown in Table 1.

### Measuring HAZE

For the cured films of Examples 1 to 5 and Comparative Examples 1 to 2, HAZE was measured. In the present invention, a HAZE value refers to a value obtained from a ratio of diffused and transmitted light with respect to total transmitted light, and a haze meter (NDH7000, manufactured by Nippon Denshoku Industries Co., Ltd.) was used to measure the HAZE. Measurement results are shown in Table 1.

### Evaluation of Film Thickness

For the cured films of Examples 1 to 5 and Comparative Examples 1 to 2, the film thicknesses were evaluated. To evaluate the film thickness, Dektak XT-A (DXT-12-0489, manufactured by Bruker Japan Co., Ltd.) was used. Evaluation results are shown in Table 1. Note that, in Table 1, a cured film having a film thickness of 5 μm or more and 10 μm or less was evaluated as A, a cured film having a film thickness of 1 μm or more and less than 1 μm was evaluated as B, and a cured film having a film thickness of less than 1 μm was evaluated as C.

### Evaluation of Adhesion

For the cured films of Examples 1 to 5 and Comparative Examples 1 to 2, adhesions were evaluated. The adhesion was evaluated in accordance with JIS K5600 May 6. Specifically, a cross-cut method was used. Evaluation results are shown in Table 1. Note that, in Table 1, the evaluation of the adhesion was carried out so that a cured film classified into 0 or 1 was evaluated as A, a cured film classified into 2 or 3 was evaluated as B, and a cured film classified into 4 or 5 was evaluated as C.

The cured films of Examples 1 to 5 exhibit a higher refractive index and a similar transmittance as compared with the cured films of Comparative Examples 1 and 2. With respect to the film thickness of the cured films, the cured films of Examples 1 to 5 have good film thicknesses, while the cured films of Comparative Examples 1 and 2 have insufficient film thicknesses. With respect to the adhesiveness of the cured films, sufficient adhesiveness was obtained in the cured films of Examples 1 to 5 and Comparative Example 1, while insufficient adhesiveness was obtained in Comparative Example 2.

1. A composition comprising at least:
a polycyclic aromatic hydrocarbon-containing polymer (I);
a scattering agent (II); and
a thiol-containing monomer (III).

2. The composition according to claim 1, wherein the polycyclic aromatic hydrocarbon-containing polymer (I) includes a fluorene structure.

3. The composition according to claim 1, wherein the scattering agent (II) is an organic or inorganic particle.

4. The composition according to claim 1, wherein a content of the scattering agent (II) is 50 to 400 mass % based on a total mass of the polycyclic aromatic hydrocarbon-containing polymer (I).

5. The composition according to claim 1, wherein a content of the thiol-containing monomer (III) is 0.1 to 20 mass % based on a total mass of the polycyclic aromatic hydrocarbon-containing polymer (I).

6. The composition according to claim 1, wherein the polycyclic aromatic hydrocarbon-containing polymer (I) includes a repeating unit having two or more (meth)acryloyloxy groups.

7. The composition according to claim 1, further comprising a compound having two or more (meth)acryloyloxy groups (IV).

8. The composition according to claim 1, further comprising a solvent (V).

9. The composition according to claim 1, further comprising a polymeric initiator (VI).

10. A manufacturing method for a cured film, comprising:
applying the composition according to claim 1 to a substrate to form a coating film; and
heating the coating film.

11. A cured film manufactured or capable of being manufactured by the method according to claim 10.

12. A cured film comprising:
a polymer (A) derived from a polycyclic aromatic hydrocarbon-containing polymer and a thiol-containing monomer; and
a scattering agent.

13. The cured film according to claim 11 having a refractive index at a wavelength of 550 nm of 1.6 or more.

14. The cured film according to claim 11, wherein a transmittance at a wavelength of 550 nm is 60% or more.

15. A display device comprising the cured film according to claim 12.
